(19) United States
(12) Patent Application Publication
(10) Pub. No.: US 2025/0219319 A1
(43) Pub. Date: Jul. 3, 2025

(54) CABLE TAP HAVING A SHIELDING PORTION STRUCTURALLY CONFIGURED TO PROVIDE ENHANCED PROTECTION AGAINST RADIO FREQUENCY INTERFERENCE AND ENVIRONMENTAL CONDITIONS

(71) Applicant: PPC BROADBAND, INC., East Syracuse, NY (US)

(72) Inventor: Roger MATHEWS, Syracuse, NY (US)

(73) Assignee: PPC BROADBAND, INC., East Syracuse, NY (US)

(21) Appl. No.: 19/005,948

(22) Filed: Dec. 30, 2024

Related U.S. Application Data
(60) Provisional application No. 63/615,669, filed on Dec. 28, 2023.

(51) Int. Cl. H01R 13/52; H01R 9/05; H01R 13/502; H01R 24/54

(52) U.S. Cl. CPC H01R 13/5202; H01R 9/0509; H01R 13/502; H01R 13/5216; H01R 24/547

(57) ABSTRACT

A cable tap structurally configured to provide enhanced protection against radio frequency interference and environmental conditions. The cable tap may include a first housing portion, a second housing portion configured to attach to the first housing portion, and a barrier portion supported on the second housing portion and structurally configured to extend into an interior of the first and second housing portions when the first and second housing portions are in a loose condition to form a physical barrier to inhibit radio frequency interference and block the ingress of rain and debris into the interior to provide enhanced protection against radio frequency interference and environmental conditions when the first and second housing portions are in the loose condition.

### CROSS-REFERENCE TO RELATED APPLICATION

This application claims the benefit of U.S. Provisional Patent Application No. 63/615,669, filed on Dec. 28, 2023, the disclosure of which is hereby incorporated by reference herein in its entirety.

### TECHNICAL FIELD

The present disclosure relates generally to cable tapping arrangements for distributing radio frequency (RF) signals in a communication network, and more particularly to cable tapping arrangements with enhanced protection against radio frequency interference and environmental conditions.

### BACKGROUND

Cable taps are used to distribute radiofrequency (RF) signals in a coaxial cable television network. A CATV network consists of interconnected coaxial cables and components such as repeating amplifiers, signal splitters, signal combiners, cable taps and other signal conveying devices to achieve two-way communication of signals between a network provider based at a “head-end” to a subscriber.

A cable tap is a passive electronic device used to distribute television signals. The cable tap is used to “tap off” a part of the available signal from the provider and send it to a TV or multiple TV's. A cable tap can include an input port, an output port (or ports), and a plurality of tap ports. Typically, the input port and the output are arranged on a back box and the plurality of tap ports are arranged on a face plate along with the circuitry to manipulate the RF signals for distribution to the home or residence in the network. The face plate is removably attached to a back box so that it can be separated from the back box for upgrades, repairs, and general duties of maintaining the network. For example, the face plate may be attached to the back box by fasteners.

Cable taps also typically include an environmental seal and RF gasketing between the mating structure of the back box and the face plate. For the environmental seal and the RF gasketing to work effectively, the back box and the face plate must be properly secured together. If the face plate and back box break contact along the mating structures (e.g., due to corrosion or if the fasteners are not tightened fully), the RF gasket and the environmental seal lose contact with the corresponding mating structure of the plate or main housing portion. As a result, unwanted egress and ingress of RF energy may occur creating interference with wireless communications and the interior of the cable tap may get exposed to environmental conditions (e.g., wind blown rain or debris) that can damage internal components.

Therefore, it may be desirable to provide a cable tap that reduces RF interference and protects the cable tap from damaging environmental conditions if the RF gasket and the environmental seal lose contact with the corresponding mating structure of the plate or main housing portion. For example, it may be desirable to provide a cable tap that includes a shielding portion structurally configured to provide electrical contact and a mechanical barrier so as to reduce RF interference and enhance environmental protection.

### SUMMARY

According to various embodiments of the present disclosure, a cable tap may be structurally configured to provide enhanced protection against radio frequency interference and environmental conditions. In some embodiments, the cable tap may include a first housing portion structurally configured to connect to an input communication cable and a first output communication cable, a second housing portion structurally configured to attach to the first housing portion and to connect to a second output communication cable and a signal processing portion structurally configured to receive and process a signal from the input communication cable and route a processed signal to the second output communication cable.

In some embodiments, the cable tap may include a shielding portion structurally configured to inhibit radio frequency interference and block the ingress of rain and debris into an interior of the first and second housing portions.

In some embodiments, the first housing portion may include a first mounting portion and the second housing portion may include a second mounting portion structurally configured to contact the first mounting portion when the second housing portion is attached to the first housing portion in a tightened condition.

In some embodiments, the shielding portion may include a first shielding portion structurally configured to engage the first housing portion and the second housing portion to form an environmental seal therebetween.

In some embodiments, the shielding portion may include a second shielding portion structurally configured to form a radio frequency barrier between the first housing portion and the second housing portion.

In some embodiments, the shielding portion may include a third shielding portion supported on the second housing portion and structurally configured to extend into the interior when the first and second housing portions are in a loose condition to form a physical barrier to inhibit radio frequency interference and block the ingress of rain and debris into the interior, wherein in the loose condition, the first mounting portion and the second mounting portion are not in contact and the signal processing portion is routing the processed signal to the output communication cable.

In some embodiments, the first shielding portion may be positioned outward of the second shielding portion.

In some embodiments, the third shielding portion may be positioned inward of the first shielding portion and outward of the signal processing portion.

In some embodiments, the first housing portion and the second housing portion may be structurally configured to enclose the signal processing portion.

In some embodiments, the shielding portion may be structurally configured to provide enhanced protection against radio frequency interference and environmental conditions when the first and second housing portions are in a loose condition.

In some embodiments, the third shielding portion may include a wall portion that extends around perimeter of the interior.

In some embodiments, the second shielding portion may be structurally configured to be supported on one of the first mounting portion, the second mounting portion, the third shielding portion, or a third mounting portion, wherein the third mounting portion is positioned within the interior.

In some embodiments, the first shielding portion may include a rubber seal and the second shielding portion may include a metal mesh.

In some embodiments, a cable tap may be structurally configured to provide enhanced protection against radio frequency interference and environmental conditions.

In some embodiments, the cable tap may include a first housing portion structurally configured to connect to an input communication cable, a second housing portion structurally configured to connect to an output communication cable, and a signal processing portion structurally configured to receive and process a signal from the input communication cable and route a processed signal to the output communication cable.

In some embodiments, the cable tap may include a shielding portion structurally configured to inhibit radio frequency interference and block the ingress of rain and debris into an interior of the first and second housing portions.

In some embodiments, the first housing portion may include a first mounting portion and the second housing portion may include a second mounting portion structurally configured to contact the first mounting portion when the second housing portion is attached to the first housing portion in a tightened condition.

In some embodiments, the shielding portion may include a first shielding portion structurally configured to engage the first housing portion and the second housing portion to form an environmental seal therebetween.

In some embodiments, the shielding portion may include a second shielding portion structurally configured to form a radio frequency barrier between the first housing portion and the second housing portion.

In some embodiments, the shielding portion may include a third shielding portion supported on the second housing portion and structurally configured to extend into the interior when the first and second housing portions are in a loose condition to form a physical barrier to inhibit radio frequency interference and block the ingress of rain and debris into the interior, wherein in the loose condition, the first mounting portion and the second mounting portion are not in contact and the signal processing portion is routing the processed signal to the output communication cable.

In some embodiments, the third shielding portion may form the physical barrier inward of the first shielding portion and outward of the signal processing portion.

In some embodiments, the first shielding portion may be positioned outward of the second shielding portion.

In some embodiments, the third shielding portion may include a wall portion that extends around perimeter of the interior space.

In some embodiments, the second shielding portion may be structurally configured to be supported on one of the first mounting portion, the second mounting portion, the third shielding portion, or a third mounting portion, wherein the third mounting portion is positioned within the interior space.

In some embodiments, the first shielding portion may include a rubber seal and the second shielding portion includes a metal mesh.

In some embodiments, a cable tap may be structurally configured to provide enhanced protection against radio frequency interference and environmental conditions. In some embodiments, the cable tap may include a first housing portion structurally configured to connect to an input communication cable, a second housing portion structurally configured to connect to an output communication cable, and a signal processing portion structurally configured to receive and process a signal from the input communication cable and route a processed signal to the output communication cable.

In some embodiments, the cable tap may include a barrier portion supported on the second housing portion and structurally configured to extend into an interior of the first and second housing portions when the first and second housing portions are in a loose condition to form a physical barrier to inhibit radio frequency interference and block the ingress of rain and debris into the interior, wherein in the loose condition, the first mounting portion and the second mounting portion are not in contact and the signal processing portion is routing the processed signal to the output communication cable.

In some embodiments, the barrier portion may be structurally configured to provide enhanced protection against radio frequency interference and environmental conditions when the first and second housing portions are in the loose condition.

In some embodiments, the cable tap may include a radio frequency gasketing portion structurally configured to form a radio frequency barrier between the first mounting portion and the second mounting portion when the second housing portion is attached to the first housing portion in the tightened condition.

In some embodiments, the barrier portion may be positioned inward of the radio frequency gasketing portion and outward of the signal processing portion.

In some embodiments, the radio frequency gasketing portion may include a metal mesh.

In some embodiments, the cable tap may include an environmental sealing portion structurally configured to engage the first housing portion and the second housing portion to form an environmental seal therebetween when the second housing portion is attached to the first housing portion in the tightened condition.

In some embodiments, the barrier portion may be positioned inward of the radio frequency gasketing portion and outward of the signal processing portion.

In some embodiments, the environmental sealing portion may include a rubber seal.

In some embodiments, the barrier portion may extend around a perimeter of the interior.

In some embodiments, the radio frequency gasketing portion may be structurally configured to be supported on one of the first mounting portion, the second mounting portion, the barrier portion, or a third mounting portion, wherein the third mounting portion is positioned within the interior.

In some embodiments, the barrier portion may include a wall portion.

Various aspects of the system, as well as other embodiments, objects, features and advantages of this disclosure, will be apparent from the following detailed description of illustrative embodiments thereof, which is to be read in conjunction with the accompanying drawings.

### BRIEF DESCRIPTION OF THE DRAWINGS

The accompanying drawings, which are incorporated in and constitute a part of this specification, illustrate embodiments of the present teachings and together with the description, serve to explain the principles of the present teachings.

FIG. 1 is a schematic representation of an example cable tapping arrangement.

FIG. 2 is a perspective view of an example cable tapping arrangement.

FIG. 3 is a top view of the cable tapping arrangement of FIG. 2 with a first housing portion separated from a second housing portion.

FIG. 4 is an enlarged view of a sectioned corner of the cable tapping arrangement of FIG. 3 showing an example shielding portion in a secure, or tightened, condition.

FIG. 5 is an enlarged view of a sectioned corner of the cable tapping arrangement of FIG. 3 showing an example shielding portion in a loose condition.

FIG. 6 is an enlarged view of a sectioned corner of the cable tapping arrangement of FIG. 3 showing an example shielding portion in a secure, or tightened, condition.

FIG. 7 is an enlarged view of a sectioned corner of the cable tapping arrangement of FIG. 3 showing an example shielding portion in a secure, or tightened, condition.

### DETAILED DESCRIPTION

Reference will now be made in detail to embodiments and methods of the present disclosure, which constitute the best modes of practicing the present disclosure presently known to the inventors. The figures are not necessarily to scale. It is to be understood, however, that the disclosed embodiments are merely exemplary of the present disclosure that may be embodied in various and alternative forms. Therefore, specific details disclosed herein are not to be interpreted as limiting, but merely as a representative basis for any aspect of the present disclosure and/or as a representative basis for teaching one skilled in the art to variously employ the present disclosure.

It is also to be understood that this present disclosure is not limited to the specific embodiments and methods described below, as specific components and/or conditions may, of course, vary. Furthermore, the terminology used herein is used only for the purpose of describing particular embodiments of the present disclosure and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

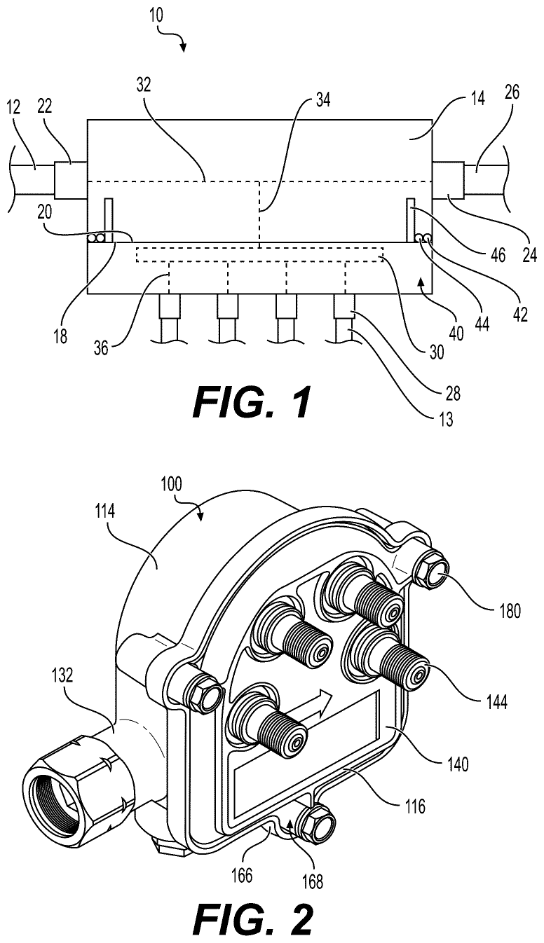

FIG. 1 shows an example cable tapping arrangement or cable tap 10 in accordance with aspects of the disclosure. The cable tapping arrangement 10 may be structurally configured to distribute radio frequency (RF) signals in a communication network (e.g., cable television network). In particular, the cable tapping arrangement 10 may be structurally configured to electrically or communicatively couple (e.g., allow for the transmission of a part of the signal of) a first input communication cable 12 (i.e., a trunk line or a feeder cable) to one or more second output communication cables 13 (e.g., a drop line) structurally configured to carry the RF signal from the cable tapping arrangement 10 to an end-use device. The cable tapping arrangement 10 may be configured in a variety of ways.

In the illustrated example, the cable tapping arrangement 10 may include a first housing portion 14 and a second housing portion 16 structurally configured to be removably coupled to the first housing portion 14. The second housing portion 16 may be removably coupled to the first housing portion 14 in a variety of ways, such as, for example, by one or more fastening members (e.g., bolt, screw, latch, clasp, clamp, catch, snap connection, etc.). In some implementations, the first housing portion 14 may include a first mounting portion 18 (e.g., a first mating surface) structurally configured to engage a second mounting portion 20 (e.g., a second mating surface) of the second housing portion 16 when the second housing portion 16 is securely attached to the first housing portion 14 (i.e., the cable tapping arrangement is in a secure, or tightened, condition).

In some implementations, the first housing portion 14 may include first cable connecting portion 22 (e.g., a first female threaded port) structurally configured to operatively connect to the first input communication cable 12 and a second cable connecting portion 24 (e.g., a second female threaded port) structurally configured to operatively connect to a first output communication cable 26.

In some implementations, the second housing portion 16 may include one or more cable tap connecting portions 28. Each of the cable tap connecting portions 28 may be structurally configured to connect to a corresponding second communication cable 13. In some implementations, the second housing portion 16 may include a signal processing portion 30 (e.g., a circuit board) structurally configured to manipulate the RF signals from the first input communication cable 12 for distribution to the cable tap connecting portions 28.

As shown in FIG. 1, in some implementations, the cable tapping arrangement 10 may be structurally configured to electrically couple the first input communication cable 12 to the first output communication cable 26, as represented by dashed line 32. Further, the cable tapping arrangement 10 may be structurally configured to electrically couple the first input communication cable 12 to the signal processing portion 30, as represented by dashed line 34. Further, the cable tapping arrangement 10 may be structurally configured to electrically couple the signal processing portion 30 to the cable tap connecting portions 28, as represented by dashed lines 36.

In some implementations, the first housing portion 14 and the second housing portion 16 may be structurally configured to provide shielding to minimize RF interference. For example, in some implementations, the first housing portion 14 and the second housing portion 16 may be made from common metal RF shielding materials (e.g., copper, aluminum, nickel, etc.). Enclosing the signal processing portion 30 and associated connectors and components inside the first housing portion 14 and the second housing portion 16 considerably reduces RF interference.

In some implementations, the cable tapping arrangement 10 may include a shielding portion 40. In some implementations, the shielding portion 40 may be structurally configured to provide shielding to minimize RF interference and/or provide protection against the ingress environmental elements (e.g., rain, dust, debris, etc.) into the cable tapping arrangement 10. In some implementations, the shielding portion 40 may be multi-faceted. For example, in some implementations, the shielding portion 40 may include a first shielding portion 42, a second shielding portion 44, and a third shielding portion 46.

In some implementations, the first shielding portion 42 (e.g., an environmental sealing portion) may be structurally configured to form an environmental seal between the first housing portion 14 and the second housing portion 16. In some implementations, the first shielding portion 42 may be structurally configured to form the environmental seal between the first mounting portion and the second mounting portion. The first shielding portion 42 may be configured in a variety of ways such as, for example, different shapes, different sizes, different locations associated with the cable tapping arrangement 10, different orientations, and different materials (e.g., any suitable material for sealing against the ingress of rain, dust, debris, etc.).

In some implementations, the second shielding portion 44 (e.g., a RF gasketing portion) may be structurally configured to form a radio frequency barrier between the first housing portion 14 and the second housing portion 16. In some implementations, the second shielding portion 44 may be structurally configured to form radio frequency barrier between the first mounting portion and the second mounting portion. The second shielding portion 44 may be configured in a variety of ways such as, for example, different shapes, different sizes, different locations associated with the cable tapping arrangement 10, different orientations, and different materials (e.g., any suitable material common metal RF shielding materials, such as copper, aluminum, nickel, etc.).

In some implementations, the third shielding portion 46 (e.g., a barrier portion) may be structurally configured to form a mechanical or structural barrier adjacent the first mounting portion 18 and the second mounting portion 20. The third shielding portion 46 may be configured in a variety of ways such as, for example, different shapes (e.g., wall, extension, etc.), different sizes, different locations associated with the cable tapping arrangement 10, different orientations, and different materials. In some implementations, the third shielding portion 46 may be structurally configured to extend from one of the first housing portion 14 or the second housing portion 16 into the other of the first housing portion 14 or the second housing portion 16.

FIGS. 2-5 show an example cable tapping arrangement or cable tap 100 in accordance with aspects of the disclosure. The cable tapping arrangement 100 may be structurally configured to distribute radio frequency (RF) signals in a communication network (e.g., cable television network). In particular, the cable tapping arrangement 100 may be structurally configured to electrically or communicatively couple (e.g., allow for the transmission of a part of the signal of) the first input communication cable 12 to one or more second communication cables 13 (FIG. 1). The cable tapping arrangement 100 may be configured in a variety of ways.

In some implementations, the cable tapping arrangement 100 may include a first housing portion 114 and a second housing portion 116 structurally configured to be removably coupled to the first housing portion 114. The first housing portion 114 may be configured in a variety of ways. In some implementations, the first housing portion 114 may include one or more walls 117 defining a first interior surface 118, a first exterior surface 120, and an interior space 122. In some implementations, the one or more walls 117 may include an edge portion 124 that defines a first mounting portion 126 and an opening 128 to the interior space 122.

In some implementations, the first housing portion 114 may include a first cable connecting portion 132 (e.g., a first female port) structurally configured to operatively connect to the first input communication cable 12 (FIG. 1) and a second cable connecting portion 134 (e.g., a second female port) structurally configured to operatively connect to the first output communication cable 26 (FIG. 1).

The second housing portion 116 may be configured in a variety of ways. In some implementations, the second housing portion 116 may include a second interior surface 138, a second exterior surface 140 opposite the second interior surface 138, and a lateral surface or edge 141 extending between the second interior surface 138 and the second exterior surface 140. In some implementations, the second interior surface 138 may include a second mounting portion 142 extending around, or adjacent to, a periphery of the second housing portion 116.

In some implementations, the second exterior surface 140 may include one or more cable tap connecting portions 144 (FIG. 2). Each of the one or more cable tap connecting portions 144 may be structurally configured to connect to a corresponding one or more second communication cables 13 (e.g., a drop line) (FIG. 1) that are structurally configured to carry the RF signal from the cable tapping arrangement 100 to an end-use device. The cable tap connecting portion 144 may be configured in a variety of ways, such as, for example, a F-Type Female connector.

The cable tapping arrangement 100 may be structurally configured to electrically couple the first input communication cable 12 to the first output communication cable 26. Further, the cable tapping arrangement 100 may be structurally configured to electrically couple the first input communication cable 12 to the one or more cable tap connecting portions 144 such that a part of the RF signal conveyed by the first input communication cable 12 may be routed to the one or more cable tap connecting portions 144. In some implementations, cable tapping arrangement 100 may include various connections and components (not shown) to facilitate conveying a part of the RF signal from the first input communication cable 12 to the one or more cable tap connecting portions 144. In some implementations, the connections and components may be conventional and known in the art.

For example, in some implementations, the cable tapping arrangement 100 may include a signal processing portion 150 (e.g., a circuit board) structurally configured to receive and process or manipulate a RF signal from the first input communication cable 12 and route the processed signal(s) to the one or more cable tap connecting portions 144. In some implementations, signal processing portion 150 may be configured in a conventional manner known in the art.

In some implementations, the signal processing portion 150 may be structurally configured to mount to the second housing portion 116. For example, in some implementations, the signal processing portion 150 may be structurally configured to mount to the second interior surface 138.

The second housing portion 116 may be removably coupled to the first housing portion 114 in a variety of ways. For example, in some implementations, the second mounting portion 142 may be structurally configured to engage or contact the first mounting portion 126 when the second housing portion 116 is coupled to the first housing portion 114. In some implementations, when the second housing portion 116 is coupled to the first housing portion 114, the second housing portion 116 may be structurally configured to cover the opening 128 to the interior space 122. In some implementations, when the second housing portion 116 covers the opening 128 to the interior space 122, the first housing portion 114 and the second housing portion 116 are structurally configured to enclose the signal processing portion 150 and the various connections and components (not shown) that facilitate conveying a part of the RF signal from the first input communication cable 12 to the one or more cable tap connecting portions 144.

In some implementations, the first housing portion 114 and the second housing portion 116 may be structurally configured to provide shielding to minimize RF interference. For example, in some implementations, the first housing portion 114 and the second housing portion 116 may be made from common metal RF shielding materials (e.g., copper, aluminum, nickel, etc.). Enclosing the signal processing portion 150 and associated connectors and components inside the first housing portion 114 and the second housing portion 116 considerably reduces RF interference.

In some implementations, the cable tapping arrangement 100 may include a shielding portion 152 structurally configured to inhibit radio frequency interference and the ingress of rain, dirt, and debris into the interior space 122 of the cable tapping arrangement 100. The shielding portion 152 may be configured in a variety of ways. In some implementations, the shielding portion 152 may be multifaceted (i.e., include a plurality of separate portions that perform shielding functions). For example, in some implementations, the shielding portion 152 may include a first shielding portion 154, a second shielding portion 156, and a third shielding portion 158. In other implementations, however, there can be more or less than three shielding portions.

In some implementations, the first shielding portion 154 (e.g., an environmental shielding portion) may be structurally configured to seal the interior space from environmental conditions (e.g., prevent the ingress of water, dirt, debris, etc.). In some implementations, the first shielding portion 154 may be structurally configured to provide a water-resistant or waterproof seal. The first shielding portion 154 may be configured in a variety of ways. In some implementations, the first shielding portion 154 may be structurally configured to be supported by the first mounting portion 126 and structurally configured to engage the second mounting portion 142 to form a seal therebetween. In other implementations, the first shielding portion 154 may be structurally configured to be supported by the second mounting portion 142 and structurally configured to engage the first mounting portion 126 to form a seal therebetween.

In some implementations, the first shielding portion 154 may be structurally configured to be received in a first groove or recess 160 in the first mounting portion 126. In some implementations, the first shielding portion 154 may be a rubber material or other suitable elastic material. In some implementations, the first shielding portion 154 may be positioned outward of the second shielding portion 156 and/or the third shielding portion 158.

In some implementations, the second shielding portion 156 (e.g., an RF gasketing portion) may be structurally configured to prevent or inhibit unwanted radio frequency egress or ingress (e.g., radio frequency interference) associated with the cable tapping arrangement 100. In some implementations, the second shielding portion 156 may be structurally configured to be supported by the first mounting portion 126 and structurally configured to engage the second mounting portion 142 to form a radio frequency barrier therebetween. In other implementations, the second shielding portion 156 may be structurally configured to be supported by the second mounting portion 142 and structurally configured to engage the first mounting portion 126 to form a radio frequency barrier therebetween.

In some implementations, the second shielding portion 156 may be structurally configured to be received in a second groove or recess 162 in the first mounting portion 126. The second shielding portion 156 may be configured in a variety of ways. In some implementations, the second shielding portion 156 may be a metal mesh material. In some implementations, the second mounting portion 142 may include a corresponding ridge or projection 164 structurally configured to engage the second shielding portion 156 when the second housing portion 116 is attached to the first housing portion 114.

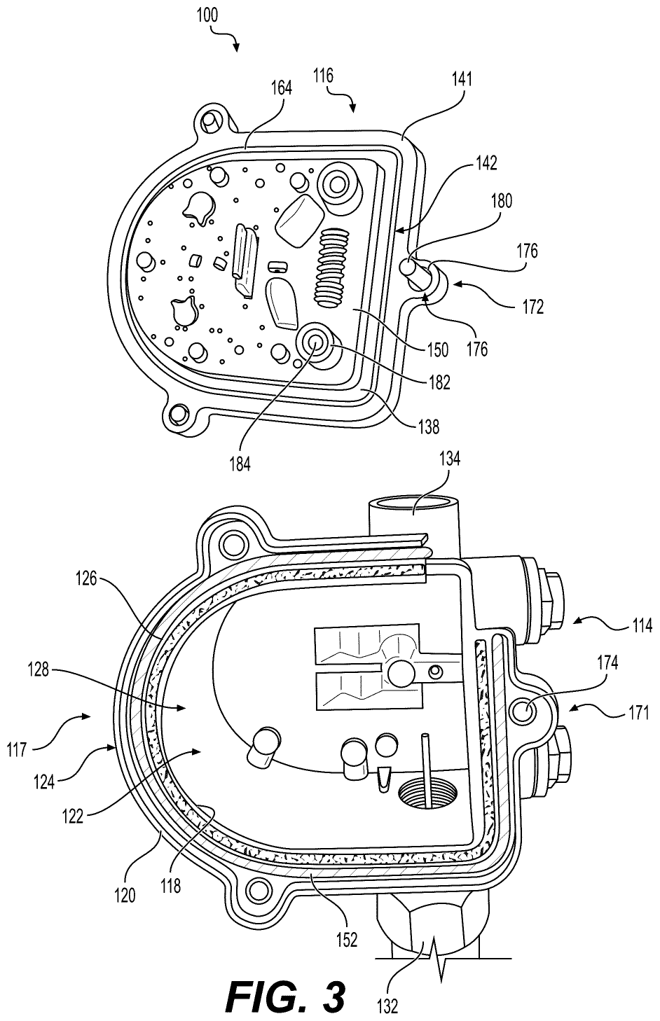

In some implementations, the third shielding portion 158 (e.g., a barrier portion) may be structurally configured to block the unwanted ingress and egress of radio frequency signals into the interior space 122 and the ingress of rain, dirt, and debris into the interior space 122. The third shielding portion 158 may be configured in a variety of ways such as, for example, different shapes (e.g., wall, extension, etc.), different sizes, different locations associated with the cable tapping arrangement 100, different orientations, and different materials. In some implementations, the third shielding portion 158 may be structurally configured to form a mechanical or structural barrier adjacent the first mounting portion 126 and the second mounting portion 142. For ease of illustration, the third shielding portion 158 is omitted from FIG. 3.

In some implementations, the third shielding portion 158 may be structurally configured to extend from one of the first housing portion 114 or the second housing portion 116 into the other of the first housing portion 114 or the second housing portion 116. In some implementations, the third shielding portion 158 may be structurally configured inward of the first shielding portion 154 and the second shielding portion 156 and outward of the signal processing portion 150. In some implementations, the third shielding portion 158 may be structurally configured to extend around a perimeter of the interior space 122.

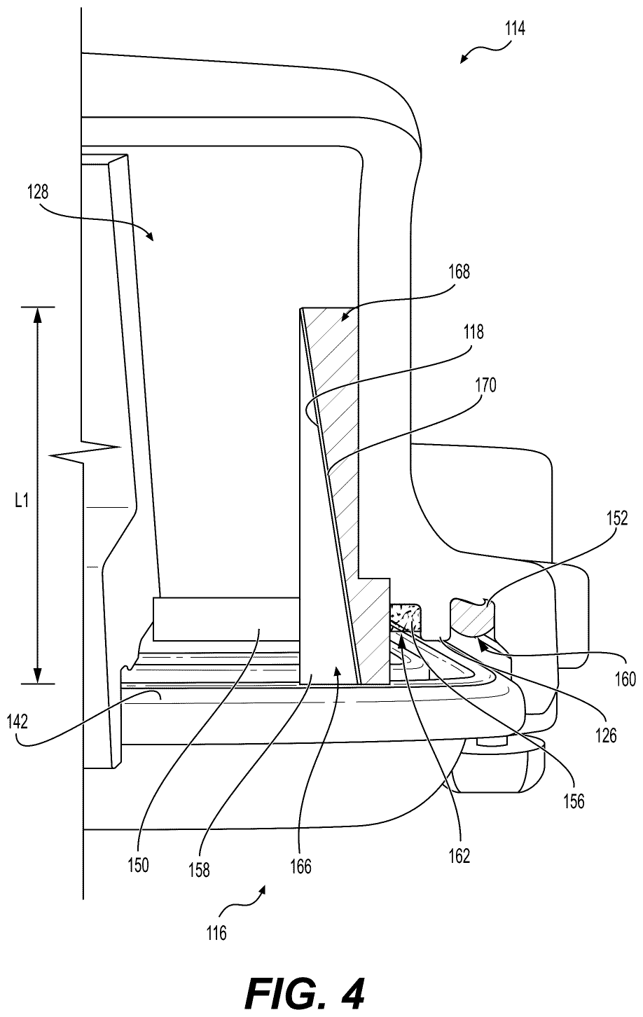

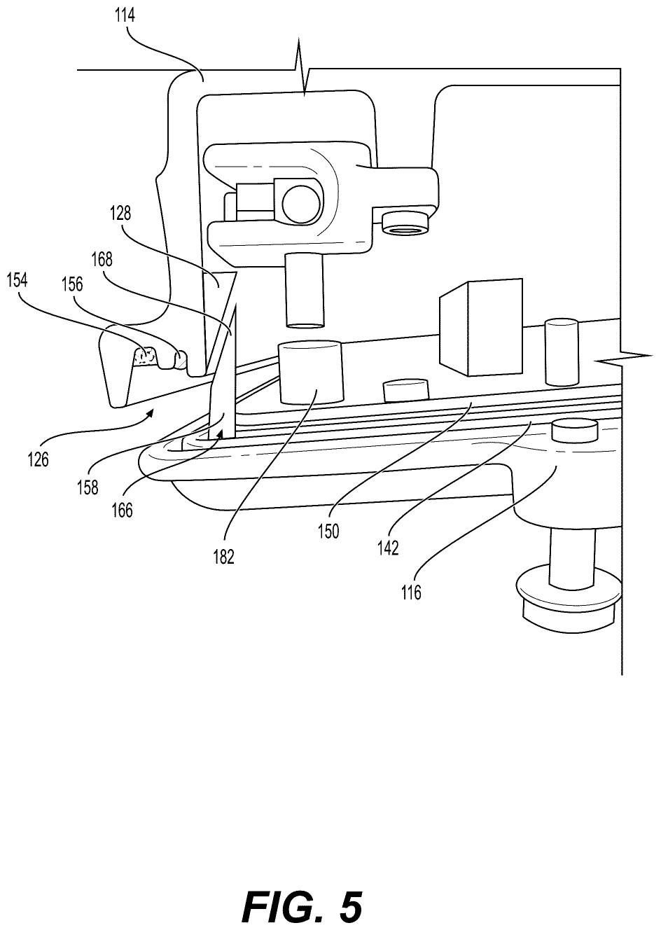

As shown in FIGS. 4-5, in some implementations, the third shielding portion 158 may be structurally configured to have a length L1, a proximal end portion 166, a distal end portion 168, and an outer lateral portion 170 extending between the distal end portion 168 and the proximal end portion 166. In some implementations, the proximal end portion 166 may be supported on the second mounting portion 142 of the second housing portion 116 and may extend into the interior space 122 to form a physical barrier or wall portion.

In some implementations, the first interior surface 118 of the first housing portion 114 may be structurally configured to be complementary to the outer lateral portion 170. For example, in some implementations, the outer lateral portion 170 may taper inward from the proximal end portion 166 to the distal end portion 168. The first interior surface 118 of the first housing portion 114 may taper inward at the same or similar angle to the outer lateral portion 170. As shown in FIG. 4, when the second housing portion 116 is securely attached to the first housing portion 114 (i.e., in a secure, or tightened, condition), the outer lateral portion 170 may engage the first housing portion 114 along the first interior surface 118 to form a barrier (e.g., a concentric wall portion extending around the perimeter of the interior space 122).

The second housing portion 116 may be secured, or tightened, to the first housing portion 114 in a variety of ways. In some implementations, the first housing portion 114 may include a first attachment portion 171 and the second housing portion 116 may include a second attachment portion 172. The first attachment portion 171 and the second attachment portion 172 may be structurally configured to cooperate with each other to secure, or tightened, the second housing portion 116 to the first housing portion 114. The first attachment portion 171 and the second attachment portion 172 may be configured in a variety of ways.

In some implementations, the first attachment portion 171 and the second attachment portion 172 are configured as a plurality of mounting bosses extending from the first exterior surface 120 and the lateral surface 141, respectively. In some implementations, the first attachment portion 171 may include a plurality of first fastening member receiving openings 174 and the second attachment portion 172 may include a plurality of second fastening member receiving openings 176.

When the second housing portion 116 is properly positioned to engage the first housing portion, each first fastening member receiving opening 174 may align with a corresponding one of the second fastening member receiving openings 176 such that a fastening member 180 may be received therethrough.

As shown in FIG. 4, in a secure, or tightened, condition, the fastening members 180 may be sufficiently tightened such that the first mounting portion 126 and the second mounting portion 142 may contact or engage each other. In the secure, or tightened, condition, first shielding portion 154 and the second shielding portion 156 may be engaged by both the first mounting portion 126 and the second mounting portion 142 to form a seal against environmental conditions and a radio frequency barrier, respectively.

In some implementations, when the second housing portion 116 is attached to the first housing portion 114, the signal processing portion 150 may be structurally configured to operatively connect to the first input communication cable 12. For example, in some implementations, the signal processing portion 150 may include a coupling portion 182 (FIGS. 3 and 5) structurally configured to operatively connect to a connector (not shown) associated with the first input communication cable 12 to operatively connect (e.g., establish an electrical connection) with first input communication cable 12. In some implementations, the coupling portion 182 may include a female port 184 structurally configured to receive a male projection or pin (not shown) associated with the first input communication cable 12.

In some implementations, the coupling portion 182 may operatively connect to the first input communication cable 12 prior to the first mounting portion 126 and the second mounting portion 142 coming into contact. For example, in some implementations, the male projection or pin (not shown) associated with the first input communication cable 12 may be received in the female port 184 before the first mounting portion 126 and the second mounting portion 142 coming into contact.

FIG. 5 illustrates the cable tapping arrangement 100 in a loose condition in which the first mounting portion 126 and the second mounting portion 142 are not in contact, but the first and second mounting portions 126, 142 are close enough that the coupling portion 182 may be operatively connect to the first input communication cable 12. This may occur, for example, when the second housing portion 116 is being removed from the first housing portion 114. This may also occur if the fastening members 180 are not sufficiently tightened such that the second mounting portion 142 separates from the first mounting portion 126.

In the loose condition, the radio frequency interference protection of enclosing the signal processing portion 150 and associated components and connections within the first and second housing portions 114, 116 and the protection provided by the second shielding portion 156 may be compromised. As a result, this may allow for the egress and ingress of unwanted radio frequency signals into the cable tapping arrangement 100 and the environment until the contact is lost between the coupling portion 182 and the signal processing portion 150. In addition, in the loose condition, the environmental protection provided by the first shielding portion 154 may also be compromised when the first shielding portion 154 does not engage the second mounting portion 142.

The third shielding portion 158, however, may be structurally configured to provide both radio frequency interference protection and protection against the ingress of environmental conditions in the loose condition (i.e., when the first mounting portion 126 and the second mounting portion 142 are not in contact, but the first and second mounting portions 126, 142 are close enough that the coupling portion 182 is operatively connected to the first input communication cable 12). As shown in FIG. 5, the length L1 (FIG. 4) may be selected such that as second housing portion 116 moves away from the first housing portion 114, the third shielding portion 158 continues to extend into the interior space 122 while the coupling portion 182 is operatively connected to the first input communication cable 12. Thus, the third shielding portion 158 provides a physical barrier to both the ingress and egress of unwanted radio frequency signals and the ingress of environmental conditions (e.g., rain, dirt, debris).

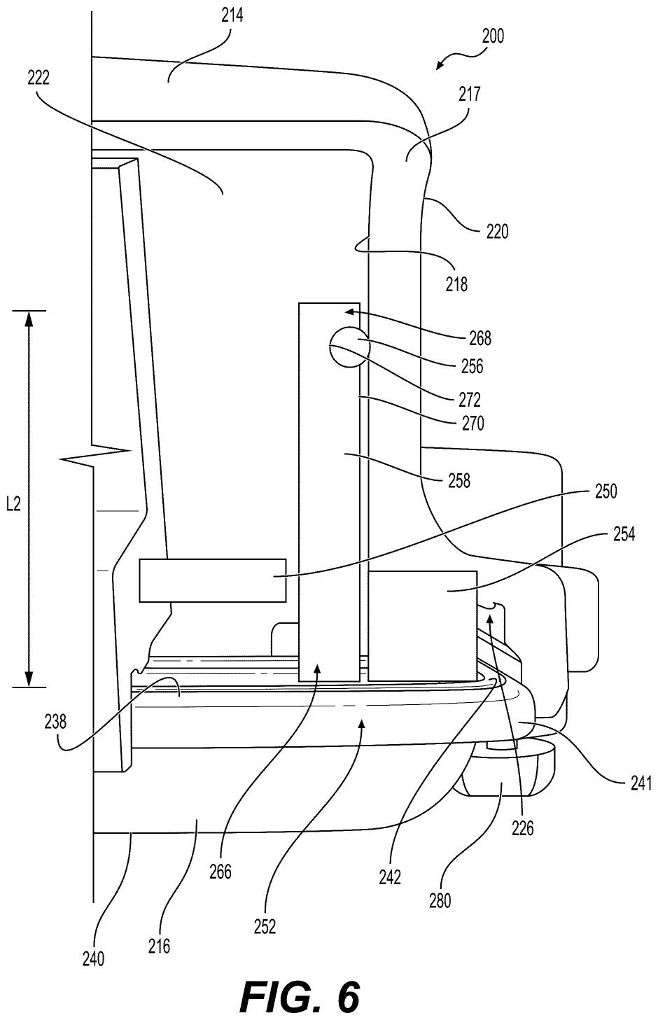

FIG. 6 shows an example cable tapping arrangement 200 in accordance with aspects of the disclosure. The cable tapping arrangement 200 may be substantially similar to the cable tapping arrangement 100 of FIGS. 2-5 and the description of the cable tapping arrangement 100 applies equally to the cable tapping arrangement 200.

The cable tapping arrangement 200 may include a first housing portion 214 and a second housing portion 216 structurally configured to be removably coupled to the first housing portion 214. The first housing portion 214 may include one or more walls 217 defining a first interior surface 218, a first exterior surface 220, and an interior space 222. In some implementations, the one or more walls 217 define a first mounting portion 226.

The second housing portion 216 may include a second interior surface 238, a second exterior surface 240 opposite the second interior surface 238, and a lateral surface or edge 241 extending between the second interior surface 238 and the second exterior surface 240. In some implementations, the second interior surface 238 may include a second mounting portion 242 extending around, or adjacent to, a periphery of the second housing portion 216.

The cable tapping arrangement 200 may include a signal processing portion 250 (e.g., a circuit board) structurally configured to receive and process or manipulate a RF signal from the first input communication cable 12 (FIG. 1). In some implementations, the signal processing portion 250 may be structurally configured to mount to the second housing portion 216, such as for example, to the second interior surface 238.

The second housing portion 216 may be removably coupled to the first housing portion 214 in a variety of ways. For example, in some implementations, the second mounting portion 242 may be structurally configured to engage or contact the first mounting portion 226 and be secured in place by one more fasteners 280.

In some implementations, the first housing portion 214 and the second housing portion 216 may be structurally configured to provide shielding to minimize RF interference. For example, in some implementations, the first housing portion 214 and the second housing portion 216 may be made from common metal RF shielding materials (e.g., copper, aluminum, nickel, etc.). Enclosing the signal processing portion 250 and associated connectors and components inside the first housing portion 214 and the second housing portion 216 considerably reduces RF interference.

In some implementations, the cable tapping arrangement 200 may include a shielding portion 252 structurally configured to inhibit radio frequency interference and the ingress of rain, dirt, and debris into the interior space 228 of the cable tapping arrangement 200. The shielding portion 252 may be configured in a variety of ways. In the illustrated implementation, the shielding portion 252 may include a first shielding portion 254, a second shielding portion 256, and a third shielding portion 258. In other implementations, however, there can be more or less than three shielding portions.

In some implementations, the first shielding portion 254 may be structurally configured to seal the interior space from environmental conditions (e.g., prevent the ingress of water, dirt, debris, etc.). In some implementations, the first shielding portion 254 may be structurally configured to provide a water-resistant or waterproof seal. The first shielding portion 254 may be configured in a variety of ways. In some implementations, the first shielding portion 254 may be structurally configured to be supported by the first mounting portion 226 and structurally configured to engage the second mounting portion 242 to form a seal therebetween. In other implementations, the first shielding portion 254 may be structurally configured to be supported by the second mounting portion 242 and structurally configured to engage the first mounting portion 226 to form a seal therebetween.

In some implementations, the first shielding portion 254 may be a rubber material or other suitable elastic material. In some implementations, the first shielding portion 254 may be positioned outward of the second shielding portion 256 and the third shielding portion 258. In some implementations, the first shielding portion 254 may be larger than the first shielding portion 154 of the cable tapping arrangement 100 because, as described below, the second shielding portion 256 may be structurally configured to be supported by the third shielding portion 258, thus; providing more room at the interface between the first mounting portion 226 and the second mounting portion 242 for a larger first shielding portion 254.

In some implementations, the second shielding portion 256 may be structurally configured to prevent or inhibit unwanted radio frequency egress or ingress (e.g., radio frequency interference) associated with the cable tapping arrangement 200. In some implementations, the second shielding portion 256 may be structurally configured to be supported by the third shielding portion 258. The second shielding portion 256 may be configured in a variety of ways. In some implementations, the second shielding portion 256 may be a metal mesh material.

In some implementations, the third shielding portion 258 may be structurally configured to block the unwanted ingress and egress of radio frequency signals into the interior space 228 and the ingress of rain, dirt, and debris into the interior space 228. The third shielding portion 258 may be configured in a variety of ways such as, for example, different shapes (e.g., wall, extension, etc.), different sizes, different locations associated with the cable tapping arrangement 200, different orientations, and different materials. In some implementations, the third shielding portion 258 may be structurally configured to form a mechanical or structural barrier adjacent the first mounting portion 226 and the second mounting portion 242.

In some implementations, the third shielding portion 258 may be structurally configured to extend from one of the first housing portion 214 or the second housing portion 216 into the other of the first housing portion 214 or the second housing portion 216. In some implementations, the third shielding portion 258 may be structurally configured inward of the first shielding portion 254 and outward of the signal processing portion 250. In some implementations, the third shielding portion 258 may be structurally configured to extend around a perimeter of the interior space 228.

In some implementations, the third shielding portion 258 may be structurally configured to have a length L2, a proximal end portion 266, a distal end portion 268, and an outer lateral portion 270 extending between the distal end portion 268 and the proximal end portion 266. In some implementations, the proximal end portion 266 may be supported on the second interior surface 338 of the second housing portion 216 and may extend into the interior space 228 to form a physical barrier or wall portion.

In some implementations, the third shielding portion 258 may include a groove or recess 262 structurally configured to receive and support the second shielding portion 256. In some implementations, the groove or recess 262 may be arranged on the outer lateral portion 270. The second shielding portion 256 may be structurally configured to be received in the groove or recess 272 and structurally configured to engage the first interior surface 218 to form a radio frequency barrier between the third shielding portion 258 and the first housing portion 214.

As shown in FIG. 6, in a secure, or tightened, condition, the fastening members 280 may be sufficiently tightened such that the first mounting portion 226 and the second mounting portion 242 may contact or engage each other. In the secure, or tightened, condition, the first shielding portion 254 may be engaged by both the first mounting portion 226 and the second mounting portion 242 to form a seal against environmental conditions. Further, the second shielding portion 256 may engage both the first interior surface 218 and the third shielding portion 258 to form a radio frequency barrier therebetween.

In the loose condition (e.g., when the second housing portion 216 is being removed from the first housing portion 214), the third shielding portion 258 provides both radio frequency interference protection and protection against the ingress of environmental conditions. The length L2 (FIG. 6) may be selected such that as second housing portion 216 moves away from the first housing portion 214, the third shielding portion 258 continues to extend into the interior space 228 while the signal processing portion 250 is operatively connected to the first input communication cable 12 (FIG. 1). Thus, the third shielding portion 258 provides a physical barrier to both the ingress and egress of unwanted radio frequency signals and the ingress of environmental conditions (e.g., rain, dirt, debris).

Further, in some implementations, as the second housing portion 216 moves away from the first housing portion 214, the second shielding portion 256 may remaining contact (e.g., slide along) with the first interior surface 218 to continue to provide shielding against unwanted radio frequency egress or ingress (e.g., radio frequency interference) into the interior space 222.

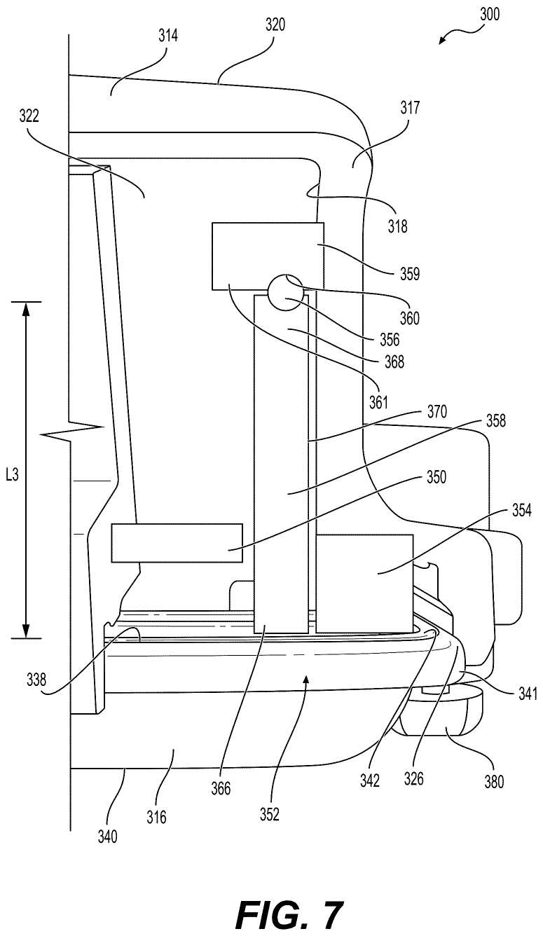

FIG. 7 shows an example cable tapping arrangement 300 in accordance with aspects of the disclosure. The cable tapping arrangement 300 may be substantially similar to the cable tapping arrangement 100 of FIGS. 2-5 and the description of the cable tapping arrangement 300 applies equally to the cable tapping arrangement 200.

The cable tapping arrangement 300 may include a first housing portion 314 and a second housing portion 316 structurally configured to be removably coupled to the first housing portion 314. The first housing portion 314 may include one or more walls 317 defining a first interior surface 318, a first exterior surface 320, and an interior space 322. In some implementations, the one or more walls 317 define a first mounting portion 326.

The second housing portion 316 may include a second interior surface 338, a second exterior surface 340 opposite the second interior surface 338, and a lateral surface or edge 341 extending between the second interior surface 338 and the second exterior surface 340. In some implementations, the second interior surface 238 may include a second mounting portion 342 extending around, or adjacent to, a periphery of the second housing portion 316.

The cable tapping arrangement 300 may include a signal processing portion 350 (e.g., a circuit board) structurally configured to receive and process or manipulate a RF signal from the first input communication cable 12 (FIG. 1). In some implementations, the signal processing portion 350 may be structurally configured to mount to the second housing portion 316, such as for example, to the second interior surface 338.

The second housing portion 316 may be removably coupled to the first housing portion 314 in a variety of ways. For example, in some implementations, the second mounting portion 342 may be structurally configured to engage or contact the first mounting portion 326 and be secured in place by one more fasteners 380.

In some implementations, the first housing portion 314 and the second housing portion 316 may be structurally configured to provide shielding to minimize RF interference. For example, in some implementations, the first housing portion 314 and the second housing portion 316 may be made from common metal RF shielding materials (e.g., copper, aluminum, nickel, etc.). Enclosing the signal processing portion 350 and associated connectors and components inside the first housing portion 314 and the second housing portion 316 considerably reduces RF interference.

In some implementations, the cable tapping arrangement 300 may include a shielding portion 352 structurally configured to inhibit radio frequency interference and the ingress of rain, dirt, and debris into the interior space 328 of the cable tapping arrangement 300. The shielding portion 352 may be configured in a variety of ways. In the illustrated implementation, the shielding portion 352 may include a first shielding portion 354, a second shielding portion 356, and a third shielding portion 358. In other implementations, however, there can be more or less than three shielding portions.

In some implementations, the first shielding portion 354 may be structurally configured to seal the interior space from environmental conditions (e.g., prevent the ingress of water, dirt, debris, etc.). In some implementations, the first shielding portion 354 may be structurally configured to provide a water-resistant or waterproof seal. The first shielding portion 354 may be configured in a variety of ways. In some implementations, the first shielding portion 354 may be structurally configured to be supported by the first mounting portion 326 and structurally configured to engage the second mounting portion 342 to form a seal therebetween. In other implementations, the first shielding portion 354 may be structurally configured to be supported by the second mounting portion 342 and structurally configured to engage the first mounting portion 326 to form a seal therebetween.

In some implementations, the first shielding portion 354 may be a rubber material or other suitable elastic material. In some implementations, the first shielding portion 354 may be positioned outward of the second shielding portion 356 and the third shielding portion 358.

In some implementations, the second shielding portion 356 may be structurally configured to prevent or inhibit unwanted radio frequency egress or ingress (e.g., radio frequency interference) associated with the cable tapping arrangement 300. In some implementations, the second shielding portion 356 may be structurally configured to be supported within the interior space 322. For example, in some implementations, the first housing portion 314 may include a third mounting portion 359 structurally configured to support the second shielding portion 356. The third mounting portion 359 may be configured in a variety of ways. In some implementations, the third mounting portion 359 may include a second groove or recess 360 structurally configured to receive and support the second shielding portion 356. In some implementations, the second groove or recess 360 may be formed in a radial shoulder portion 361. In some implementations, the second shielding portion 256 may be a metal mesh material.

In some implementations, the third shielding portion 358 may be structurally configured to block the unwanted ingress and egress of radio frequency signals into the interior space 328 and the ingress of rain, dirt, and debris into the interior space 328. The third shielding portion 358 may be configured in a variety of ways such as, for example, different shapes (e.g., wall, extension, etc.), different sizes, different locations associated with the cable tapping arrangement 300, different orientations, and different materials. In some implementations, the third shielding portion 358 may be structurally configured to form a mechanical or structural barrier adjacent the first mounting portion 326 and the second mounting portion 342.

In some implementations, the third shielding portion 358 may be structurally configured to extend from one of the first housing portion 314 or the second housing portion 316 into the other of the first housing portion 314 or the second housing portion 316. In some implementations, the third shielding portion 358 may be structurally configured inward of the first shielding portion 354 and outward of the signal processing portion 350. In some implementations, the third shielding portion 358 may be structurally configured to extend around a perimeter of the interior space 328.

In some implementations, the third shielding portion 358 may be structurally configured to have length L3, a proximal end portion 366, a distal end portion 368, and an outer lateral portion 370 extending between the distal end portion 368 and the proximal end portion 366. In some implementations, the proximal end portion 366 may be supported on the second interior surface 338 of the second housing portion 316 and may extend into the interior space 328 to form a physical barrier or wall portion.

As shown in FIG. 7, in a secure, or tightened, condition, the fastening members 380 may be sufficiently tightened such that the first mounting portion 326 and the second mounting portion 342 may contact or engage each other. In the secure, or tightened, condition, the first shielding portion 354 may be engaged by both the first mounting portion 326 and the second mounting portion 342 to form a seal against environmental conditions. Further, the second shielding portion 356 may engage both third mounting portion 359 and the distal end portion 368 of the third shielding portion 258 to form a radio frequency barrier therebetween.

In the loose condition (e.g., when the second housing portion 316 is being removed from the first housing portion 314), the third shielding portion 358 provides both radio frequency interference protection and protection against the ingress of environmental conditions. The length L3 (FIG. 7) may be selected such that as second housing portion 316 moves away from the first housing portion 314, the third shielding portion 358 continues to extend into the interior space 328 while the signal processing portion 350 is operatively connected to the first input communication cable 12 (FIG. 1). Thus, the third shielding portion 358 provides a physical barrier to both the ingress and egress of unwanted radio frequency signals and the ingress of environmental conditions (e.g., rain, dirt, debris).

While at least one example, non-limiting embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A cable tap structurally configured to provide enhanced protection against radio frequency interference and environmental conditions, comprising:
a first housing portion structurally configured to connect to an input communication cable and a first output communication cable;
a second housing portion structurally configured to attach to the first housing portion and to connect to a second output communication cable;
a signal processing portion structurally configured to receive and process a signal from the input communication cable and route a processed signal to the second output communication cable; and
a shielding portion structurally configured to inhibit radio frequency interference and block the ingress of rain and debris into an interior of the first and second housing portions;
wherein the first housing portion includes a first mounting portion, and wherein the second housing portion includes a second mounting portion structurally configured to contact the first mounting portion when the second housing portion is attached to the first housing portion in a tightened condition;
wherein the shielding portion includes a first shielding portion structurally configured to engage the first housing portion and the second housing portion to form an environmental seal therebetween;
wherein the shielding portion includes a second shielding portion structurally configured to form a radio frequency barrier between the first housing portion and the second housing portion;
wherein the shielding portion includes a third shielding portion supported on the second housing portion and structurally configured to extend into the interior when the first and second housing portions are in a loose condition to form a physical barrier to inhibit radio frequency interference and block the ingress of rain and debris into the interior, wherein in the loose condition, the first mounting portion and the second mounting portion are not in contact and the signal processing portion is routing the processed signal to the second output communication cable;
wherein the first shielding portion is positioned outward of the second shielding portion;
wherein the third shielding portion is positioned inward of the first shielding portion and outward of the signal processing portion;
wherein the first housing portion and the second housing portion are structurally configured to enclose the signal processing portion; and
wherein the shielding portion is structurally configured to provide enhanced protection against radio frequency interference and environmental conditions when the first and second housing portions are in a loose condition.

2. The cable tap of claim 1, wherein the third shielding portion includes a wall portion that extends around perimeter of the interior.

3. The cable tap of claim 1, wherein the second shielding portion is structurally configured to be supported on one of the first mounting portion, the second mounting portion, the third shielding portion, or a third mounting portion, wherein the third mounting portion is positioned within the interior.

4. The cable tap of claim 1, wherein the first shielding portion includes a rubber seal and the second shielding portion includes a metal mesh.

5. A cable tap structurally configured to provide enhanced protection against radio frequency interference and environmental conditions, comprising:
a first housing portion structurally configured to connect to an input communication cable;
a second housing portion structurally configured to connect to an output communication cable;
a signal processing portion structurally configured to receive and process a signal from the input communication cable and route a processed signal to the output communication cable; and
a shielding portion structurally configured to inhibit radio frequency interference and block the ingress of rain and debris into an interior of the first and second housing portions;
wherein the first housing portion includes a first mounting portion, and wherein the second housing portion includes a second mounting portion structurally configured to contact the first mounting portion when the second housing portion is attached to the first housing portion in a tightened condition;
wherein the shielding portion includes a first shielding portion structurally configured to engage the first housing portion and the second housing portion to form an environmental seal therebetween;
wherein the shielding portion includes a second shielding portion structurally configured to form a radio frequency barrier between the first housing portion and the second housing portion; and
wherein the shielding portion includes a third shielding portion supported on the second housing portion and structurally configured to extend into the interior when the first and second housing portions are in a loose condition to form a physical barrier to inhibit radio frequency interference and block the ingress of rain and debris into the interior, wherein in the loose condition, the first mounting portion and the second mounting portion are not in contact and the signal processing portion is routing the processed signal to the output communication cable.

6. The cable tap of claim 5, wherein the third shielding portion forms the physical barrier inward of the first shielding portion and outward of the signal processing portion.

7. The cable tap of claim 5, wherein the first shielding portion is positioned outward of the second shielding portion.

8. The cable tap of claim 5, wherein the third shielding portion includes a wall portion that extends around perimeter of the interior.

9. The cable tap of claim 5, wherein the second shielding portion is structurally configured to be supported on one of the first mounting portion, the second mounting portion, the third shielding portion, or a third mounting portion, wherein the third mounting portion is positioned within the interior.

10. The cable tap of claim 5, wherein the first shielding portion includes a rubber seal and the second shielding portion includes a metal mesh.

11. A cable tap structurally configured to provide enhanced protection against radio frequency interference and environmental conditions, comprising:
a first housing portion structurally configured to connect to an input communication cable;
a second housing portion structurally configured to connect to an output communication cable;
a signal processing portion structurally configured to receive and process a signal from the input communication cable and route a processed signal to the output communication cable;
a barrier portion supported on the second housing portion and structurally configured to extend into an interior of the first and second housing portions when the first and second housing portions are in a loose condition to form a physical barrier to inhibit radio frequency interference and block the ingress of rain and debris into the interior, wherein in the loose condition, the first mounting portion and the second mounting portion are not in contact and the signal processing portion is routing the processed signal to the output communication cable; and
wherein the barrier portion is structurally configured to provide enhanced protection against radio frequency interference and environmental conditions when the first and second housing portions are in the loose condition.

12. The cable tap of claim 11, further comprising a radio frequency gasketing portion structurally configured to form a radio frequency barrier between the first mounting portion and the second mounting portion when the second housing portion is attached to the first housing portion in a tightened condition.

13. The cable tap of claim 12, wherein the barrier portion is positioned inward of the radio frequency gasketing portion and outward of the signal processing portion.

14. The cable tap of claim 12, wherein the radio frequency gasketing portion includes a metal mesh.

15. The cable tap of claim 12, wherein the barrier portion is positioned inward of the radio frequency gasketing portion and outward of the signal processing portion.

16. The cable tap of claim 11, further comprising an environmental sealing portion structurally configured to engage the first housing portion and the second housing portion to form an environmental seal therebetween when the second housing portion is attached to the first housing portion in a tightened condition.

17. The cable tap of claim 16, wherein the environmental sealing portion includes a rubber seal.

18. The cable tap of claim 11, wherein the barrier portion extends around a perimeter of the interior.

19. The cable tap of claim 12, wherein the radio frequency gasketing portion is structurally configured to be supported on one of the first mounting portion, the second mounting portion, the barrier portion, or a third mounting portion, wherein the third mounting portion is positioned within the interior.

20. The cable tap of claim 11, wherein the barrier portion includes a wall portion.
